(19) United States
(12) Patent Application Publication
(10) Pub. No.: US 2025/0077853 A1
(43) Pub. Date: Mar. 6, 2025

(54) BINARIZED NEURAL NETWORK CIRCUITRY USING SILICON-GATED DIODES

(71) Applicant: Korea University Research and Business Foundation, Seoul (KR)

(72) Inventors: Sang Sig KIM, Seoul (KR); Kyoung Ah CHO, Seoul (KR); Yun Woo SHIN, Gwangmyeong-si (KR)

(73) Assignee: Korea University Research and Business Foundation, Seoul (KR)

(21) Appl. No.: 18/396,409

(22) Filed: Dec. 26, 2023

(30) Foreign Application Priority Data
Aug. 30, 2023 (KR) 10-2023-0114457

(51) Int. Cl. G06N 3/065; G06N 3/04

(52) U.S. Cl. CPC G06N 3/065; G06N 3/04

(57) ABSTRACT

The present disclosure relates to a binarized neural network circuitry using silicon-gated diodes. The binarized neural network circuitry according to one embodiment of the present disclosure includes a plurality of silicon-gated diodes in which a diode structure as a channel area is located between an anode terminal and a cathode terminal, a gate terminal is located on the diode structure to implement unidirectional switching through potential barrier control in the channel area based on different voltages applied to each of the anode terminal and the gate terminal, and memory characteristics are realized as holes or electrons accumulate in the potential well due to a positive feedback loop. In addition, in the binarized neural network circuitry, the silicon-gated diodes operate as synaptic elements in a memory array connected in parallel, and the results of a multiply-accumulate (MAC) operation are output based on an input signal applied from an input line processor connected to the memory array and a weight update signal applied from a synapse line processor connected to the memory array.

### TECHNICAL FIELD

The present disclosure relates to a binarized neural network circuitry using silicon-gated diodes, and more particularly, to a technology for implementing a self-activating binarized neural network circuitry that performs a self-activating function using a silicon-gated diode that performs memory and switching functions in a single element based on a positive feedback loop.

### BACKGROUND ART

In a conventional von Neumann-based computer system, a processor and a memory are separated and data signals are transmitted through a bus line.

As computing performance improves, a bottleneck phenomenon occurs due to a difference in data processing speed between a processor and a memory, and there are limits to processing large amounts of data.

That is, the von Neumann-based system, which is a product of revolutionary development in the semiconductor industry, has improved the integration density and performance of modern computers, but has the disadvantage of consuming much energy and having long data transmission and standby times due to the physical separation between a processor and a memory hierarchy.

Considering the increase in data-intensive applications such as 5G communication standards, Internet of Things (IoT), and Artificial Intelligence (AI) after the Fourth Industrial Revolution, a new computing paradigm is an essential requirement for large-scale data processing.

To solve the above-mentioned problems, research is being actively conducted on logic-in-memory (LIM) technology that combines calculation and memory functions.

According to the logic-in-memory technology, since the calculating function of a processor and the memory function of a memory are performed in the same space, the time and power required during data transmission may be reduced, and the integration of the system may be greatly improved.

The conventional logic-in-memory technology has been actively researched based on static random-access memory (SRAM) and dynamic RAM (DRAM), which are volatile memory elements, and resistive RAM (ReRAM), magnetoresistive RAM (MRAM), and phase-change RAM (PCRAM), which are non-volatile memory elements.

To overcome limitations in processing large amounts of data, Package-on-Package (POP) and through-silicon via (TSV) technologies, which integrate logic memory into a single chip, are being researched. However, since logic and memory functions are not performed simultaneously in a transistor, problems related to the bottleneck phenomenon, power consumption, computational efficiency, and integration still remain.

In addition, in the case of logic-in-memory technology based on a non-volatile memory element, a complex manufacturing process is required because non-silicon materials are used. In addition, this technology has low element uniformity and stability, making it difficult to put into practical use.

In addition, previously researched logic-in-memory technologies cannot implement all basic complementary metal-oxide semiconductor (CMOS) logic operations in one cell and have low integration because individual circuitry and wiring are required for each logic operation.

Accordingly, the development of a binarized neural network technology using silicon-gated diodes that can be applied to the CMOS process and perform both switching and memory functions simultaneously and a self-activated neural network technology that performs the activation function of a neuron circuitry in a neural network is required.

### RELATED ART DOCUMENTS

### Patent Documents

(Patent Document 1) Korean Patent Application Publication No. 10-2023-0053195, “STATEFUL LOGIC-IN-MEMORY USING SILICON DIODES”
(Patent Document 2) Korean Patent Application Publication No. 10-2022-0110774, “PERFORMANCE-AND AREA-EFFICIENT SYNAPTIC MEMORY CELL STRUCTURE”
(Patent Document 3) Korean Patent Application Publication No. 10-2023-0020840, “VARIABLE LOGIC-IN-MEMORY ELEMENT USING SILICON TRANSISTORS”
(Patent Document 4) Korean Patent Application Publication No. 10-2022-0107808, “MIXED SIGNAL BINARIZED NEURAL NETWORK CIRCUITRY DEVICE”

### DISCLOSURE

### Technical Problem

Therefore, the present disclosure has been made in view of the above problems, and it is an object of the present disclosure to implement a self-activating binarized neural network circuitry that performs a self-activating function using a silicon-gated diode that performs memory and switching functions in a single element based on a positive feedback loop.

It is another object of the present disclosure to implement a self-activating binarized neural network circuitry having unidirectional switching characteristics by controlling a potential barrier; and being capable of increasing the area and computational efficiency of an artificial neural network by having excellent memory characteristics of a silicon-gated diode that also has memory characteristics as holes or electrons accumulate in a potential well due to a positive feedback loop and a self-activating function through the linearity of an output signal according to an input signal.

It is still another object of the present disclosure to increase the computational accuracy of an artificial neural network by enabling the use of the CMOS process, enabling the fabrication of large-scale arrays, and almost eliminating the deviation between the characteristics of a silicon-gated diode and the characteristics of a synaptic device.

It is still another object of the present disclosure to implement a binarized neural network circuitry including a memory array that is composed of silicon-gated diodes based on a positive feedback loop and performs the activation function of a neuron circuitry; and having excellent uniformity and stability.

It is yet another object of the present disclosure to implement a binarized neural network circuitry capable of reducing standby power by using the excellent memory characteristics of silicon-gated diodes; and capable of being used in the next-generation artificial intelligence computing technology by increasing computational efficiency with low power consumption through excellent switching characteristics.

### Technical Solution

In accordance with one aspect of the present disclosure, provided is a binarized neural network circuitry including a plurality of silicon-gated diodes in which a diode structure as a channel area is located between an anode terminal and a cathode terminal, a gate terminal is located on the diode structure to implement unidirectional switching through potential barrier control in the channel area based on different voltages applied to each of the anode terminal and the gate terminal, and memory characteristics are realized as holes or electrons accumulate in the potential well due to a positive feedback loop, wherein the silicon-gated diodes operate as synaptic elements in a memory array connected in parallel, and results of a multiply-accumulate (MAC) operation are output based on an input signal applied from an input line processor connected to the memory array and a weight update signal applied from a synapse line processor connected to the memory array.

The silicon-gated diode may receive an anode voltage of the anode terminal as the input signal, generate a latch-up phenomenon due to the positive feedback loop as the applied input signal increases in a positive direction, have any one of two memory states for the channel area, receive a gate voltage of the gate terminal as the weight update signal to control the input signal causing the latch-up phenomenon, update a synaptic state associated with the memory state according to application of the input signal and the weight update signal, and perform the MAC calculating function according to the synaptic weight.

The silicon-gated diode may output a current signal corresponding to any one of “0” to “1” as an operation result by performing a multiplication operation between a continuous input from “0” to “1” as the applied input signal increases in a positive direction and a synaptic weight of any one of a “0” state and a “1” state corresponding to the two memory states.

In the silicon-gated diode, in a case of a potentiation operation in which the synaptic weight is updated to the “1” state, an operation result may be output as a current signal in proportion to the applied input signal, and in a case of a depression operation in which the synaptic weight is updated to the “0” state, a current signal may be output at 0 mA regardless of the applied input signal.

When the synaptic weight is in a “1” state, the silicon-gated diode may output a cathode current of the cathode terminal in a form similar to a graph shape of a rectified linear unit (ReLU) function, regardless of the gate voltage.

The memory array may connect the anode terminal, the gate terminal, and the cathode terminal in parallel in the silicon-gated diodes to form an input line, a weight line, and an output line, respectively. The input line may be arranged perpendicular to the weight line and the output line, and the weight line and the output line may be arranged in parallel.

The input line may receive the input signal, the weight line may receive the weight update signal, and the output line may output the MAC operation result based on the input signal and the weight update signal to a next artificial neural network.

In the memory array, the silicon-gated diodes may be connected in a form of N×M, and through a multiplication operation of a synaptic weight that is updated based on an input signal applied to the input line and a weight update signal applied to the weight line, each current may be added through the output line and a sum operation may be performed to output the MAC operation results as a synaptic weight matrix.

In the memory array, when the N and the M are “2”, the input signal may consist of a first input signal and a second input signal, the synaptic weight may consist of a first synaptic weight to a fourth synaptic weight, a first current and a second current may be output to the output line, and the synaptic weight matrix consisting of the first current and the second current may be calculated as a result of a vector matrix multiplication operation of the synaptic weight and the input signal.

In the memory array, when both the first and second input signals are applied while the weight update signal is fixed at 1 V, a value of the first current may be twice a value of the second current, and afterwards, when only the first input signal is applied, a value of the first current may be equal to a value of the second current.

In the memory array, when only the second input signal is applied, only the first current may have a value proportional to the second input signal, and when the first input signal and the second input signal are not applied, the first current and the second current may be measured close to 0 mA.

The silicon-gated diode may include any one of a single silicon-gated diode, a double silicon-gated diode, and a triple silicon-gated diode.

### Advantageous Effects

The present disclosure can implement a self-activating binarized neural network circuitry that performs a self-activating function using a silicon-gated diode that performs memory and switching functions in a single element based on a positive feedback loop.

The present disclosure can implement a self-activating binarized neural network circuitry having unidirectional switching characteristics by controlling a potential barrier; and being capable of increasing the area and computational efficiency of an artificial neural network by having excellent memory characteristics of a silicon-gated diode that also has memory characteristics as holes or electrons accumulate in a potential well due to a positive feedback loop and a self-activating function through the linearity of an output signal according to an input signal.

The present disclosure can increase the computational accuracy of an artificial neural network by enabling the use of the CMOS process, enabling the fabrication of large-scale arrays, and almost eliminating the deviation between the characteristics of a silicon-gated diode and the characteristics of a synaptic device.

The present disclosure can implement a binarized neural network circuitry including a memory array that is composed of silicon-gated diodes based on a positive feedback loop and performs the activation function of a neuron circuitry; and having excellent uniformity and stability.

The present disclosure can implement a binarized neural network circuitry capable of reducing standby power by using the excellent memory characteristics of silicon-gated diodes; and capable of being used in the next-generation artificial intelligence computing technology by increasing computational efficiency with low power consumption through excellent switching characteristics.

### DESCRIPTION OF DRAWINGS

FIGS. 1A to 2B are diagrams explaining the structures and circuitry symbols of a silicon-gated diode that constitutes a binarized neural network circuitry according to one embodiment of the present disclosure.

FIGS. 3A to 3C are diagrams explaining the electrical properties of a silicon-gated diode that constitutes a binarized neural network circuitry according to one embodiment of the present disclosure.

FIG. 4 is a diagram explaining a binarized neural network circuitry using silicon-gated diodes according to one embodiment of the present disclosure.

FIGS. 5A to 6B are diagrams explaining a multiplication operation in a method of operating a binarized neural network circuitry using silicon-gated diodes according to one embodiment of the present disclosure.

FIGS. 7A to 9F are diagrams explaining a multiply-accumulate (MAC) operation in a method of operating a binarized neural network circuitry using silicon-gated diodes according to one embodiment of the present disclosure.

FIG. 10 includes the optical images of a silicon-gated diode according to one embodiment of the present disclosure.

FIGS. 11A to 11C are diagrams explaining the arithmetic operations of a binarized neural network circuitry using silicon-gated diodes according to one embodiment of the present disclosure.

### BEST MODE

Hereinafter, the embodiments of the present disclosure will be described in detail with reference to the drawings.

However, it should be understood that the present disclosure is not limited to the embodiments according to the concept of the present disclosure, but includes changes, equivalents, or alternatives falling within the spirit and scope of the present disclosure.

In the following description of the present disclosure, detailed description of known functions and configurations incorporated herein will be omitted when it may make the subject matter of the present disclosure unclear.

In addition, the terms used in the specification are defined in consideration of functions used in the present disclosure, and can be changed according to the intent or conventionally used methods of clients, operators, and users. Accordingly, definitions of the terms should be understood on the basis of the entire description of the present specification.

In description of the drawings, like reference numerals may be used for similar elements.

The singular expressions in the present specification may encompass plural expressions unless clearly specified otherwise in context.

In this specification, expressions such as “A or B” and “at least one of A and/or B” may include all possible combinations of the items listed together.

Expressions such as “first” and “second” may be used to qualify the elements irrespective of order or importance, and are used to distinguish one element from another and do not limit the elements.

It will be understood that when an element (e.g., first) is referred to as being “connected to” or “coupled to” another element (e.g., second), the first element may be directly connected to the second element or may be connected to the second element via an intervening element (e.g., third).

As used herein, “configured to” may be used interchangeably with, for example, “suitable for”, “ability to”, “changed to”, “made to”, “capable of”, or “designed to” in terms of hardware or software.

In some situations, the expression “device configured to” may mean that the device “may do ˜” with other devices or components.

For example, in the sentence “processor configured to perform A, B, and C”, the processor may refer to a general purpose processor (e.g., CPU or application processor) capable of performing corresponding operation by running a dedicated processor (e.g., embedded processor) for performing the corresponding operation, or one or more software programs stored in a memory device.

In addition, the expression “or” means “inclusive or” rather than “exclusive or”.

That is, unless mentioned otherwise or clearly inferred from context, the expression “x uses a or b” means any one of natural inclusive permutations.

Terms, such as “unit” or “module”, etc., should be understood as a unit that processes at least one function or operation and that may be embodied in a hardware manner, a software manner, or a combination of the hardware manner and the software manner.

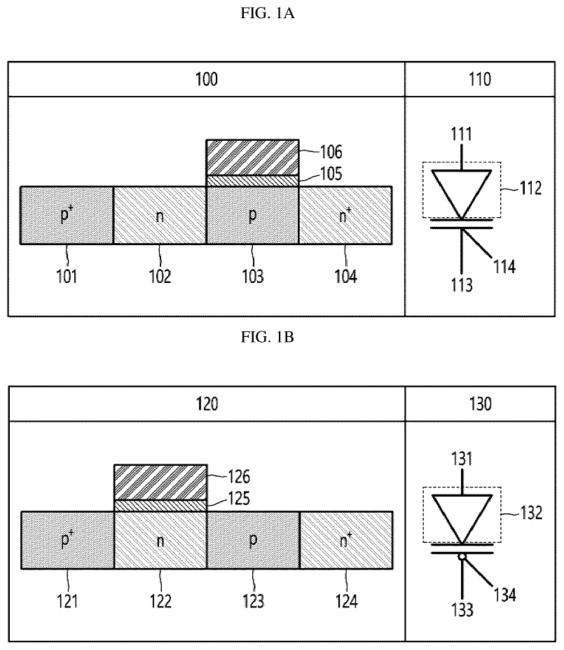

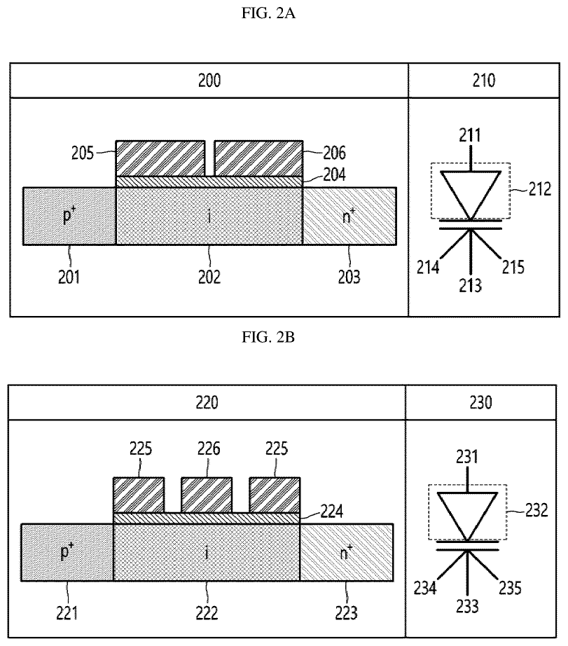

FIGS. 1A to 2B are diagrams explaining the structures and circuitry symbols of a silicon-gated diode that constitutes a binarized neural network circuitry according to one embodiment of the present disclosure.

FIGS. 1A and 1B illustrate the structures and circuitry symbols of the silicon-gated diode that constitutes the binarized neural network circuitry according to one embodiment of the present disclosure.

Referring to FIG. 1A, in a silicon-gated diode 100 that constitutes the binarized neural network circuitry according to one embodiment of the present disclosure, a channel area between an anode terminal 101 and a cathode terminal 104 consists of a first channel area 102 and a second channel area 103.

A gate insulating film 105 is located on the second channel area 103, and a gate terminal 106 is located on the gate insulating film 105.

In a circuitry symbol 110 of the silicon-gated diode that constitutes the binarized neural network circuitry according to one embodiment of the present disclosure, a channel area 112 is located between an anode terminal 111 and a cathode terminal 113, and a gate terminal 114 is connected thereto.

Referring to FIG. 1B, in a silicon-gated diode 120 that constitutes the binarized neural network circuitry according to one embodiment of the present disclosure, a channel area between an anode terminal 121 and a cathode terminal 124 consists of a first channel area 122 and a second channel area 123.

A gate insulating film 125 is located on the first channel area 122, and a gate terminal 126 is located on the gate insulating film 125.

In a circuitry symbol 130 of the silicon-gated diode that constitutes the binarized neural network circuitry according to one embodiment of the present disclosure, a channel area 132 is located between an anode terminal 131 and a cathode terminal 133, and a gate terminal 134 is connected thereto.

According to one embodiment of the present disclosure, an input line is connected to the anode terminal 111 or the anode terminal 131, an output line is connected to the cathode terminal 113 or the cathode terminal 133, and the memory state of the channel area is determined according to the update of a synaptic weight.

FIG. 2A illustrates the structure and circuitry symbol of a double silicon-gated diode that constitutes the binarized neural network circuitry according to one embodiment of the present disclosure.

Referring to FIG. 2A, in a silicon-gated diode 200 that constitutes the binarized neural network circuitry according to one embodiment of the present disclosure, an intrinsic area 202 is located between an anode terminal 201 and a cathode terminal 203, a gate insulating film 204 is located on the intrinsic area 202, and a first gate terminal 205 and a second gate terminal 206 are located on the gate insulating film 204.

The intrinsic area 202 operates as a channel area based on a gate voltage input from any one of the first gate terminal 205 and the second gate terminal 206.

In a circuitry symbol 210 of the silicon-gated diode that constitutes the binarized neural network circuitry according to one embodiment of the present disclosure, an intrinsic area 212 is located between an anode terminal 211 and a cathode terminal 213, and a first gate terminal 214 and a second gate terminal 215 are connected thereto.

FIG. 2B illustrates the structure and circuitry symbol of a triple silicon-gated diode that constitutes the binarized neural network circuitry according to one embodiment of the present disclosure.

Referring to FIG. 2B, in a silicon-gated diode 220 that constitutes the binarized neural network circuitry according to one embodiment of the present disclosure, an intrinsic area 222 is located between an anode terminal 221 and a cathode terminal 223, a gate insulating film 224 is located on the intrinsic area 222, and a programming gate terminal 225 and a control gate terminal 226 are located on the gate insulating film 224.

The intrinsic area 222 operates as a channel area based on a gate voltage input from the programming gate terminal 225.

More specifically, when the level of a program voltage (VPG) input from the intrinsic area 222 to the programming gate terminal 225 is high, the intrinsic area 222 operates as an n channel corresponding to a first channel operation. When the level of the program voltage (VPG) is low, the intrinsic area 222 operates as a p channel corresponding to a second channel operation.

When the first channel operation is performed, when the level of a control voltage (VCG) input through the control gate terminal 226 is high, the silicon-gated diode 220 is determined to be in the on state. When the level of a control voltage (VCG) input through the control gate terminal 226 is low, the silicon-gated diode 220 is determined to be in the off state.

In a circuitry symbol 230 of the silicon-gated diode that constitutes the binarized neural network circuitry according to one embodiment of the present disclosure, an intrinsic area 232 is located between an anode terminal 231 and a cathode terminal 233, and a programming gate terminal 234 and a control gate terminal 235 are connected thereto.

For example, the anode terminal, the gate terminal, and the cathode terminal may be referred to as an anode electrode, a gate electrode, and a cathode electrode, respectively.

That is, the silicon-gated diode that constitutes the binarized neural network circuitry according to one embodiment of the present disclosure may have a structure in which, on a silicon channel, a single gated electrode terminal is deposited on an n- or p-type doped channel area or multiple gated electrode terminals are deposited on an intrinsically doped area.

In addition, the silicon-gated diode operates through the induction of a positive feedback loop by a potential barrier and has switching and memory characteristics, so the silicon-gated diode may be configured as a synaptic element of the binarized neural network.

That is, the silicon-gated diode has switching and memory characteristics, making it possible to implement a self-activating binarized neural network circuitry in which the activation function of a neuron circuitry is performed by a neural network.

Accordingly, the present disclosure may implement a self-activating binarized neural network circuitry that performs a self-activating function using a silicon-gated diode that performs memory and switching functions in a single element based on a positive feedback loop.

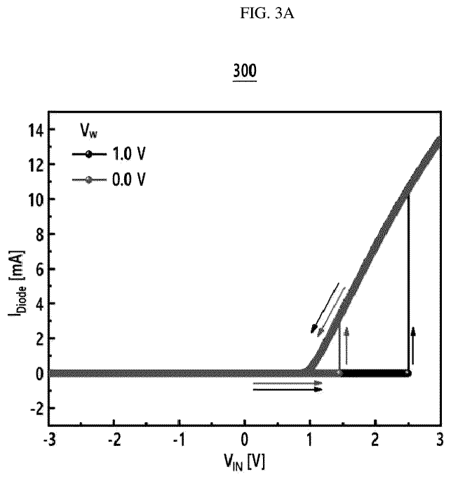

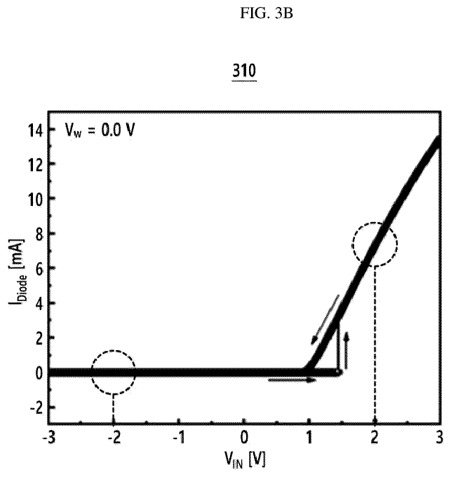

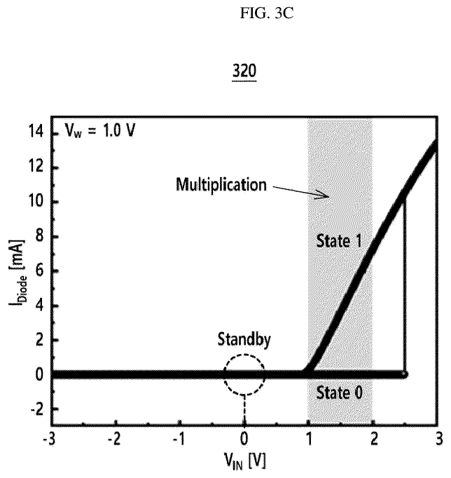

FIGS. 3A to 3C are diagrams explaining the electrical properties of a silicon-gated diode that constitutes the binarized neural network circuitry according to one embodiment of the present disclosure.

FIGS. 3A to 3C show the electrical properties of the silicon-gated diode that constitutes the binarized neural network circuitry according to one embodiment of the present disclosure.

Referring to FIG. 3A, a graph 300 related to the electrical properties of the silicon-gated diode that constitutes the binarized neural network circuitry according to one embodiment of the present disclosure shows a change in cathode current (I_{Diode}) output to a cathode terminal according to an anode voltage (V_{IN}) applied to an anode terminal.

The graph 300 shows that, when the silicon-gated diode that constitutes the binarized neural network circuitry increases an anode voltage (V_{IN}) in the positive direction, a latch-up phenomenon occurs due to a positive feedback loop and two states are exhibited.

In addition, the anode voltage at which latch-up occurs varies depending on the gate voltage (V_{W}) of the silicon-gated diode.

The binarized neural network circuitry may perform synaptic weight update and multiply-accumulate (MAC) calculating functions by applying an anode voltage and a gate voltage based on the characteristics of the single element.

Regardless of the gate voltage, the cathode current (I_{Diode}) of an element in the “1” state may be similar to the graph shape of the rectified linear unit (ReLU) function.

The ReLU function may be the activation function of a neuron circuitry used in most artificial neural network architectures.

That is, in the silicon-gated diode that constitutes the binarized neural network of the present disclosure, the output current has the shape of the ReLU function in the synaptic weight state of “1” regardless of the gate voltage, so a self-activating binarized neural network circuitry that self-activates a neuron circuitry may be implemented.

Through the unidirectional switching or self-rectification characteristics and high linearity of a single silicon-gated diode, a self-activating binarized neural network that performs a self-activating function may be implemented.

Referring to FIG. 3B, a graph 310 related to the electrical properties of the silicon-gated diode that constitutes the binarized neural network circuitry according to one embodiment of the present disclosure shows the case in which the gate voltage (V_{W}) of the silicon-gated diode is 0 V in relation to a change in cathode current (I_{Diode}) output to a cathode terminal according to an anode voltage (V_{IN}) applied to an anode terminal.

Referring to FIG. 3C, a graph 320 related to the electrical properties of the silicon-gated diode that constitutes the binarized neural network circuitry according to one embodiment of the present disclosure shows the case in which the gate voltage (V_{W}) of the silicon-gated diode is 1 V in relation to a change in cathode current (I_{Diode}) output to a cathode terminal according to an anode voltage (V_{IN}) applied to an anode terminal.

When the anode voltage (V_{IN}) is 0 V, it may be in a standby state.

A graph 320 shows the Bayesian neural network (BNN) operating conditions, in which the cathode current (I_{Diode}) increases rapidly when the gate voltage (V_{W}) is 1 V at about 2.5 V as the anode voltage (V_{IN}) increases.

The graph 320 shows that a positive feedback loop is eliminated at around 1 V as the anode voltage (V_{IN}) decreases.

The bistable nature is expressed as cathode current (I_{Diode}) to anode voltage (V_{IN}) and the high ratio of current magnitudes of states 1 and 0 may be about 108.

When a gate voltage (V_{W}) is 1 V for an anode voltage (V_{IN}) of 2 V, the electrical properties of a p-n diode are inherited with unipolar switching characteristics.

Regardless of the gate voltage (V_{W}), the shape of the curve for cathode current (I_{Diode}) versus anode voltage (V_{IN}) in state 1 is similar to the shape of the rectified linear unit function used in the activation function of a neural network.

The difference in cathode current (I_{Diode}) depending on the change between state 1 and state 0 may be used in MAC operation.

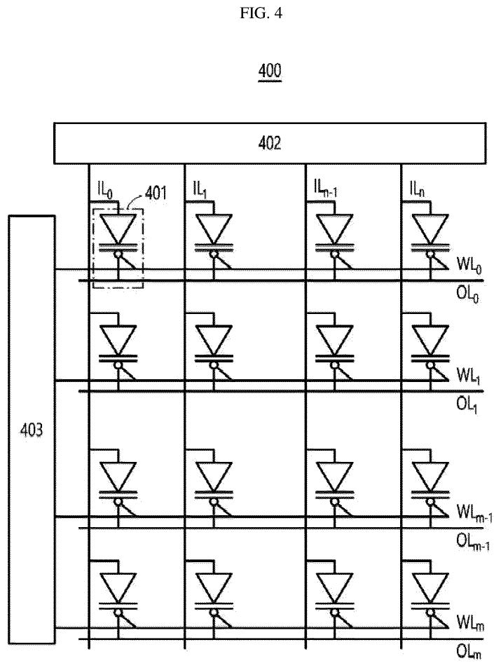

FIG. 4 is a diagram explaining a binarized neural network circuitry using silicon-gated diodes according to one embodiment of the present disclosure.

FIG. 4 illustrates the binarized neural network circuitry using silicon-gated diodes according to one embodiment of the present disclosure.

Referring to FIG. 4, in a binarized neural network circuitry 400 using silicon-gated diodes according to one embodiment of the present disclosure, a diode structure as a channel area is located between an anode terminal and a cathode terminal, and a gate terminal is located on the diode structure. With this configuration, unidirectional switching is implemented through potential barrier control in the channel area based on different voltages applied to each of the anode terminal and the gate terminal. In addition, multiple silicon-gated diodes may be included to implement memory characteristics as holes or electrons accumulate in the potential well due to a positive feedback loop.

For example, the binarized neural network circuitry 400 using silicon-gated diodes may be an artificial neural network that reduces calculation time and power consumption by binarizing synaptic weights.

Accordingly, the present disclosure may implement a self-activating binarized neural network circuitry having unidirectional switching characteristics by controlling a potential barrier; and being capable of increasing the area and computational efficiency of an artificial neural network by having excellent memory characteristics of a silicon-gated diode that also has memory characteristics as holes or electrons accumulate in a potential well due to a positive feedback loop and a self-activating function through the linearity of an output signal according to an input signal.

A plurality of silicon-gated diodes may operate as synaptic elements 401 in a memory array connected in parallel and may output multiply-accumulate (MAC) operation results based on an input signal applied from an input line processor 402 connected to the memory array and a weight update signal applied from a synapse line processor 403 connected to the memory array.

In the memory array as the binarized neural network circuitry 400, in a plurality of silicon-gated diodes, an anode terminal, a gate terminal, and a cathode terminal may be connected in parallel to form an input line (IL), a weight line (WL), and an output line (OL), respectively. The input line (IL) may be arranged perpendicular to the weight line (WL) and output line (OL), and the weight line (WL) and the output line (OL) may be arranged parallel to each other.

The anode terminal is connected to the input line (IL), the gate terminal is connected to the weight line (WL), and the cathode terminal is connected to the output line (OL).

The gate terminal and the cathode terminal may form the weight line (WL) and the output line (OL), respectively.

For example, in the memory array, depending on M which is the number of rows formed by a plurality of silicon-gated diodes, the first weight line (WL₀) to the M-th weight line (WLₘ) may be configured, and the first output line (OL₀) to the M-th output line (OLₘ) may be configured.

The number of input lines (IL) corresponding to columns and the number of output lines (OL) corresponding to rows may be the same or different.

However, the weight line (WL) and the output line (OL) must have the same number (M).

For example, since the number of elements constituting rows and columns may be as many as the number of inputs and outputs, N and M may be the same number or different numbers.

For example, in the memory array, depending on N which is the number of columns formed by a plurality of silicon-gated diodes, the first input line (IL₀) to the N-th input line (ILₙ) may be configured.

The silicon-gated diode receives the anode voltage of the anode terminal as an input signal, and generates a latch-up phenomenon due to a positive feedback loop as the applied input signal increases in the positive direction.

The silicon-gated diode has one of two memory states for the channel area. The silicon-gated diode receives the gate voltage of the gate terminal as a weight update signal, so the input signal at which the latch-up phenomenon occurs may be controlled.

In addition, the silicon-gated diode may update a synaptic state related to any one memory state according to the application of an input signal and a weight update signal, and may perform a MAC calculating function according to a synaptic weight.

For example, the silicon-gated diode may output, as an operation result, a current signal corresponding to any one of “0” to “1” by performing a multiplication operation between a continuous input from “0” to “1” as the applied input signal increases in the positive direction and a synaptic weight of any one of two memory states of “0” and “1”.

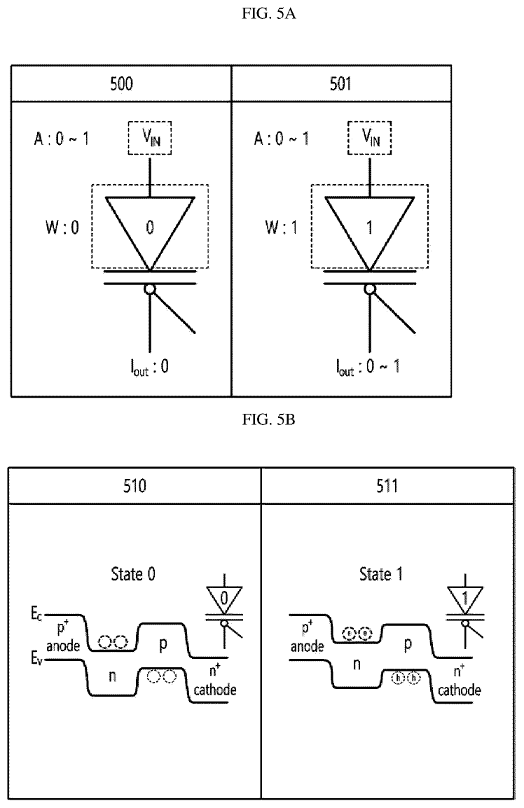

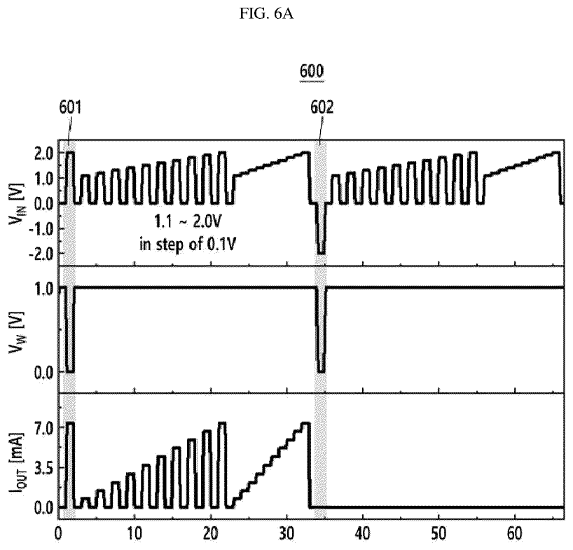

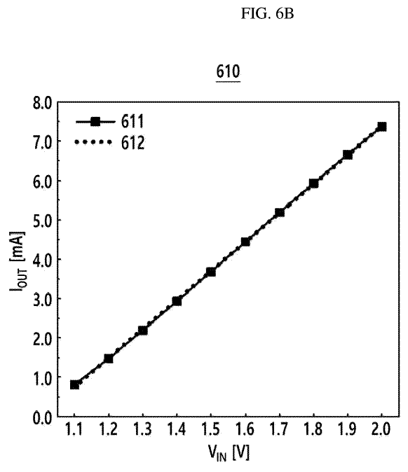

FIGS. 5A to 6B are diagrams explaining a multiplication operation in a method of operating a binarized neural network circuitry using silicon-gated diodes according to one embodiment of the present disclosure.

FIG. 5A illustrates a multiplication operation in the method of operating the binarized neural network circuitry using silicon-gated diodes according to one embodiment of the present disclosure.

Referring to FIG. 5A, in the method of operating the binarized neural network circuitry using silicon-gated diodes according to one embodiment of the present disclosure, cases are divided into a first case 500 and a second case 501, and a MAC operation is performed between an input signal and a synaptic weight.

Accordingly, the binarized neural network circuitry may implement artificial intelligence functions such as image recognition through a continuous multi-layer neural network.

The synaptic weight may be updated through the input voltage of an input line and a weight line.

The input signal (V_{IN}) applied through the input line may have continuous values, which may mean a continuous input A from 0 to 1 in the binarized neural network.

The current signal (I_{OUT}) corresponding to an output may be read through OL, and at this time, the input A may have the form of a ReLU function for the input signal (V_{IN}) due to the self-activation characteristics of the silicon-gated diode.

The operations corresponding to the first case 500 and the second case 501 are summarized in Table 1 below.

TABLE 1

| | Anode voltage | Synaptic weight | Output |
|---|---|---|---|
| | (A) | (W) | (OUT) |
| First case | 0~1 | 0 | 0 |
| Second case | | 1 | 0~1 |

The silicon-gated diode has two memory states, a “1” state and a “0” state, which may, respectively, mean a binarized synaptic weight W (0) and a binarized synaptic weight W (1).

In the first case 500, when the synaptic weight W is 0, since the case means that the silicon-gated diode is turned off (“0” state), regardless of the applied input signal (V_{IN}), the output current (I_{OUT}) flows at a very low level.

Regarding the anode voltage (A) of 0˜1, a voltage below the reference voltage corresponds to 0, and a voltage greater than the reference voltage corresponds to 1.

For example, when the reference voltage is 1 V, a voltage greater than 1 V may correspond to 1.

In addition, in the output, a current greater than the reference current of 0 to 1 is output as 1, and a current smaller than the reference current is output as 0.

This may mean that the multiplication operation result of an anode voltage and a synaptic weight in the MAC operation of the binarized neural network is always 0 regardless of an input signal.

In the second case 501, when the synaptic weight W is 1, since the case means that the silicon-gated diode is turned on (“1” state), the output current (I_{OUT}) may change linearly in proportion to the applied input signal (V_{IN}).

This means that, in the MAC operation of the binarized neural network, the multiplication operation result of an anode voltage and a synaptic weight may be proportional to an input.

According to one embodiment of the present disclosure, the silicon-gated diode may output a current signal corresponding to any one of “0” to “1” as an operation result by performing a multiplication operation between a continuous input from “0” to “1” as an applied input signal increases in the positive direction and the synaptic weight of one of two memory states of “0” and “1”.

Here, in relation to inputs from “0” to “1” as the input signals increase or decrease in the positive direction, a voltage below the reference voltage corresponds to “0”, and a voltage greater than the reference voltage corresponds to “1”.

For example, when the reference voltage is 1 V, a voltage greater than 1 V may correspond to “1”.

FIG. 5B shows energy band diagrams according to state change of a silicon-gated diode in the method of operating the binarized neural network circuitry using silicon-gated diodes according to one embodiment of the present disclosure.

Referring to FIG. 5B, a first energy band diagram 510 may indicate that the state of the silicon-gated diode is “0”, and a second energy band diagram 511 may indicate that the state of the silicon-gated diode is “1”.

In state “0” according to the first energy band diagram 510, excess charge carriers are absent in the potential wells of the n- and p-doping regions of the energy band diagram, preventing diode current (I_{Diode}) from flowing into a diode.

In contrast, in state “1” according to the second energy band diagram 511, excess charge carriers accumulate in the potential wells of the n- and p-doping regions of the energy band diagram, causing diode current to flow into a diode.

Modulating a potential barrier allows the diode to exhibit bistable properties.

A weight voltage of 0 V is applied when performing potentiation and depression operations, and a weight voltage of 1 V is applied when performing standby and multiplication operations.

The conductance of state “0” and state “1” may be the conductance of an element that varies depending on the presence or absence of charge in a potential well depending on a rising or depression operation.

FIG. 6A shows the timing diagram of a multiplication operation in the method of operating the binarized neural network circuitry using silicon-gated diodes according to one embodiment of the present disclosure.

Referring to FIG. 6A, a timing diagram 600 may exhibit a corresponding rising section 601 after the weight “1” update, may exhibit a corresponding depression section 602 after the weight “0” update, while an output current (I_{OUT}) is measured in proportion to a continuous input signal (V_{IN}) pulse, and regardless of an input signal (V_{IN}), a low output current (I_{OUT}) of 0 mA may be measured.

According to one embodiment of the present disclosure, in the silicon-gated diode, in the case of a potentiation operation in which a synaptic weight is updated to the state of “1”, an operation result is output as a current signal in proportion to an applied input signal. In the case of a depression operation in which a synaptic weight is updated to the state of “0”, a current signal may be output as 0 mA regardless of an applied input signal.

When a synaptic weight is in the state of “1”, regardless of a gate voltage, the silicon-gated diode may output the cathode current of a cathode terminal in a form similar to the graph shape of a rectified linear unit (ReLU) function.

To update the synaptic weight W to 1 according to the operation method in the timing diagram 600, the voltage pulses of an input voltage (V_{IN}) of 2 V applied to an anode terminal and a synaptic weight voltage (V_{W}) of 0 V applied to a gate terminal are applied.

Thereafter, continuous I_{OUT} from 0 mA to 7.4 mA may be measured proportional to continuous V_{IN} from 1.1 to 2.0 V.

To update the synaptic weight (W) to 0, the voltage pulses of V_{IN} of 2 V and V_{W} of 0 V may be applied.

At this time, regardless of the same input voltage (VA), a very low level output current close to 0 mA may be measured.

This shows that a single synaptic element performs a multiplication operation based on excellent linearity.

Referring to FIG. 6B, in a graph 610, the silicon-gated diode shows an excellent linear relationship between input and output and may perform multiplication operations.

The graph 610 shows an experiment result 611 and straight fitting 612.

Accordingly, the present disclosure may increase the computational accuracy of an artificial neural network by enabling the use of the CMOS process, enabling the fabrication of large-scale arrays, and almost eliminating the deviation between the characteristics of a silicon-gated diode and the characteristics of a synaptic device.

Technologies using conventional next-generation memories, such as ReRAM and MRAM, have the disadvantages of not being able to apply the CMOS process, poor element uniformity and stability, and being difficult to put into practical use due to complex processing processes.

In conventional artificial neural network technology, multiple neural network layers are connected through an activation function, but to implement this, a complex additional neuron circuitry is required, which may deteriorate the area and energy efficiency of an artificial neural network.

However, the present disclosure may implement a binarized neural network circuitry capable of reducing standby power by using the excellent memory characteristics of silicon-gated diodes; and capable of being used in the next-generation artificial intelligence computing technology by increasing computational efficiency with low power consumption through excellent switching characteristics.

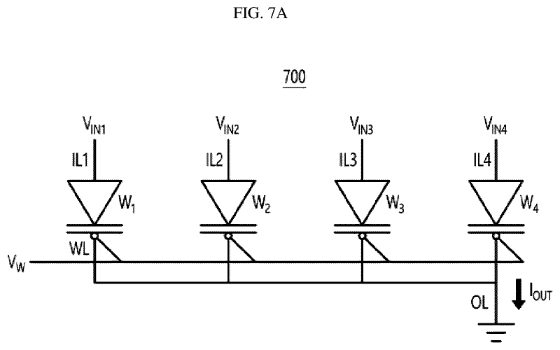

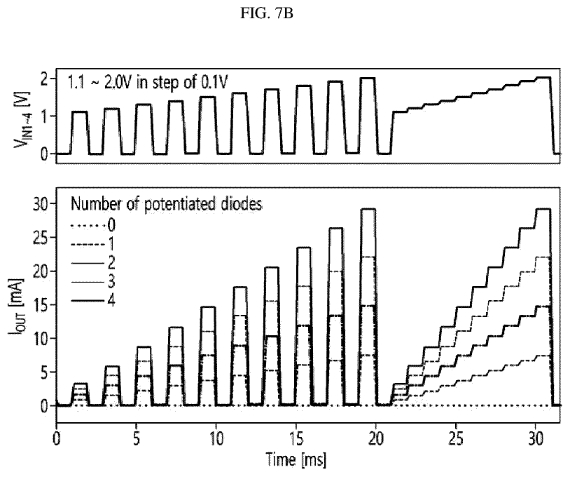

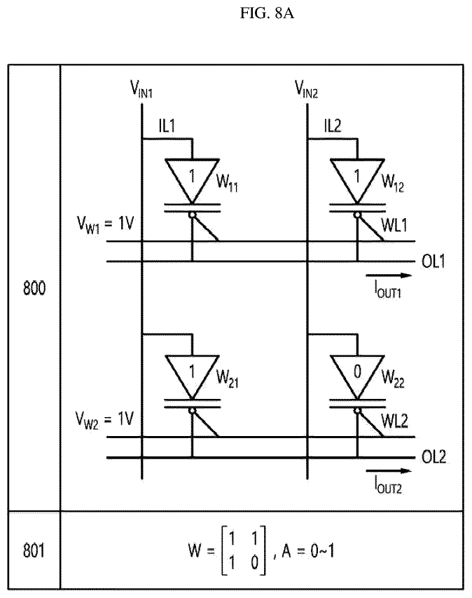

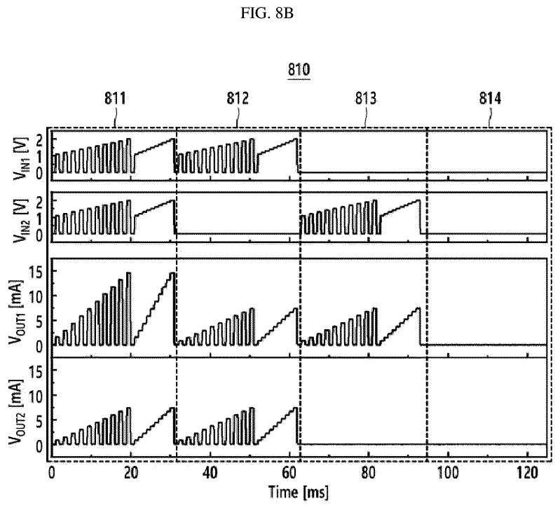

FIGS. 7A to 8B are diagrams explaining a multiply-accumulate (MAC) operation in the method of operating the binarized neural network circuitry using silicon-gated diodes according to one embodiment of the present disclosure.

FIGS. 7A and 7B illustrate a case in which a memory array consisting of silicon-gated diodes connected in a 4×1 pattern is used in relation to an MAC operation in the method of operating the binarized neural network circuitry using silicon-gated diodes according to one embodiment of the present disclosure.

Referring to FIG. 7A, in a memory array 700 corresponding to the binarized neural network circuitry according to one embodiment of the present disclosure, an output current is added to an output current (I_{OUT}) through a common output line (OL), and a sum operation is performed.

Referring to FIG. 7B, in a timing diagram 710 corresponding to the binarized neural network circuitry according to one embodiment of the present disclosure, the input voltage (V_{IN1} to V_{IN4}) of the input line increases from 1.1 V to 2 V by 0.1 V per step.

The timing diagram 710 shows the results of a sum operation in which an output current from each diode is added to the output current (I_{OUT}) through the common output line (OL).

FIGS. 8A and 8B show a matrix MAC operation in relation to an MAC operation in the method of operating the binarized neural network circuitry using silicon-gated diodes according to one embodiment of the present disclosure.

FIG. 8A shows a binarized neural network circuitry 800 using silicon-gated diodes according to one embodiment of the present disclosure and a synaptic weight matrix 801 according to the operation of the binarized neural network circuitry.

FIG. 8B shows the binarized neural network circuitry 800 using silicon-gated diodes according to one embodiment of the present disclosure and a timing diagram 810 related to the operation of the binarized neural network circuitry.

The MAC operation of the binarized neural network uses a silicon-gated diode array connected in a 2×2 form as the binarized neural network circuitry 800.

In the memory array related to the binarized neural network circuitry 800, a plurality of silicon-gated diodes are connected in an N×N form. Through the multiplication operation of a synaptic weight that is updated based on an input signal applied to an input line and a weight update signal applied to a weight line, each current is added through the output line, a sum operation is performed, and the MAC operation result may be output to a synaptic weight matrix.

In addition, in the memory array, when N is “2”, the input signal consists of a first input signal and a second input signal, the synaptic weight consists of a first synaptic weight to a fourth synaptic weight and a first current and a second current output to the output line, and the synaptic weight matrix consisting of the first current and the second current may be calculated as the result of a vector matrix multiplication operation of the synaptic weight and the input signal.

The silicon-gated diode may perform multiplication operations of each input signal (V_{IN1}, V_{IN2}) and synaptic weights (W₁₁, W₁₂, W₂₁, W₂₂), and may perform a sum operation in which each output current (I_{OUT1}, I_{OUT2}) is added through the common first output line (O_{L1}) and the second output line (O_{L2}).

That is, mathematically, the 2×2 array may perform a vector-matrix multiplication operation

$$( [ \begin{matrix}{W}_{11} & {W}_{12} \\ {W}_{21} & {W}_{22}\end{matrix} ] [ \begin{matrix}{IN}_{1} \\ {IN}_{2}\end{matrix} ] = [ \begin{matrix}{OUT}_{1} \\ {OUT}_{2}\end{matrix} ] ) ,$$

and the synaptic weight matrix 801 is exemplified as

$$[ \begin{matrix}1 & 1 \\ 1 & 0\end{matrix} ] .$$

In the binarized neural network circuitry 800, after updating the synaptic weight of each element, when both V_{IN1} and V_{IN2} are applied while V_{W} is fixed at 1 V, I_{OUT1} has exactly twice the value of I_{OUT2}. Afterwards, when only V_{IN1} is applied, I_{OUT1} and I_{OUT2} have the same value.

Conversely, when only V_{IN2} is applied, only I_{OUT1} may have a value proportional to the input signal.

Lastly, when all input signals are not applied, both I_{OUT1} and I_{OUT2} may be measured at low levels.

These results are consistent with the multiplication operation between the input vector and the synaptic weight matrix.

A silicon-gated diode array connected in a 2×2 form through the binarized neural network circuitry 800 may implement the MAC operation of a self-activating binarized neural network.

The binarized neural network circuitry 800 is described in a 2×2 form, but may be expanded to an N×M form.

The timing diagram 810 shows that, in a first area 811, when both V_{IN1} and V_{IN2} are applied with V_{W} fixed at 1 V, I_{OUT1} has exactly twice the value of I_{OUT2}.

A second area 812 shows that I_{OUT1} and I_{OUT2} may have the same value when only V_{IN1} is applied.

A third area 813 shows that, when only V_{IN2} is applied, only I_{OUT1} may have a value proportional to the input signal.

A fourth area 814 shows that both I_{OUT1} and I_{OUT2} may be measured at low levels when no input signal is applied.

That is, in the memory array related to the binarized neural network circuitry 800, when both the first and second input signals are applied while the weight update signal is fixed at 1 V, the value of the first current is twice that of the second current. Afterwards, when only the first input signal is applied, the first current and the second current may have the same value.

In addition, in the memory array, when only the second input signal is applied, only the first current has a value proportional to the second input signal. When the first input signal and the second input signal are not applied, the first current and the second current may be measured to be approximate 0 mA.

Accordingly, the present disclosure may implement a binarized neural network circuitry including a memory array that is composed of silicon-gated diodes based on a positive feedback loop and performs the activation function of a neuron circuitry; and having excellent uniformity and stability.

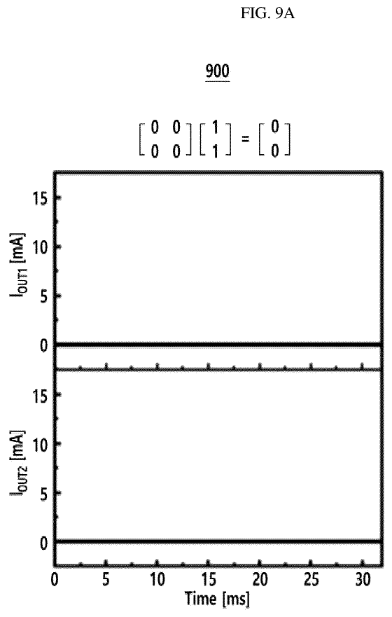

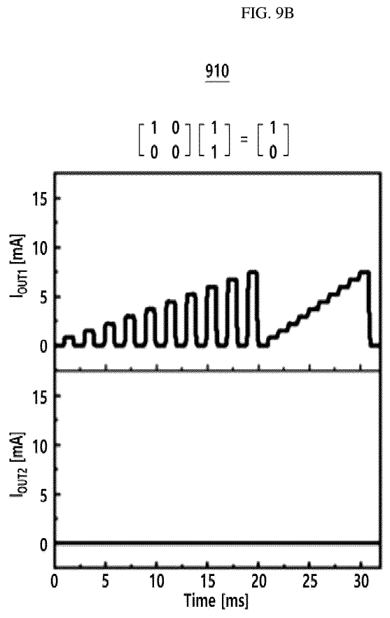

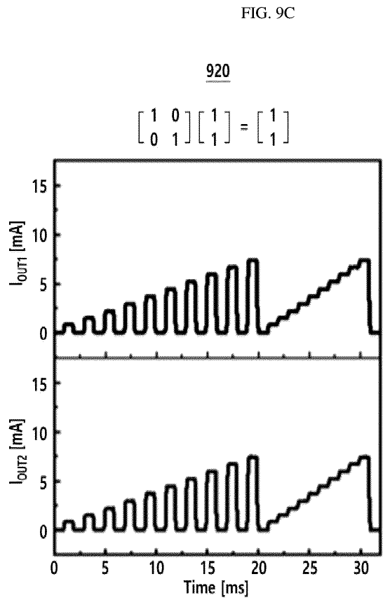

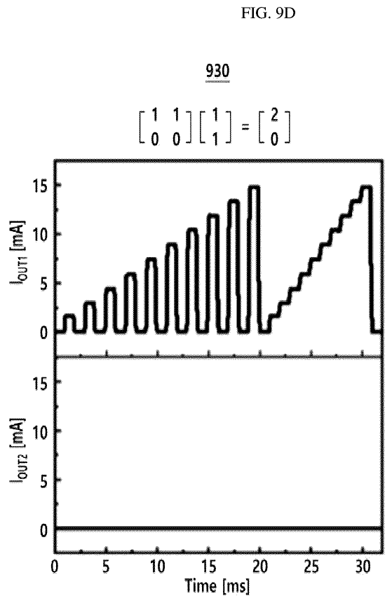

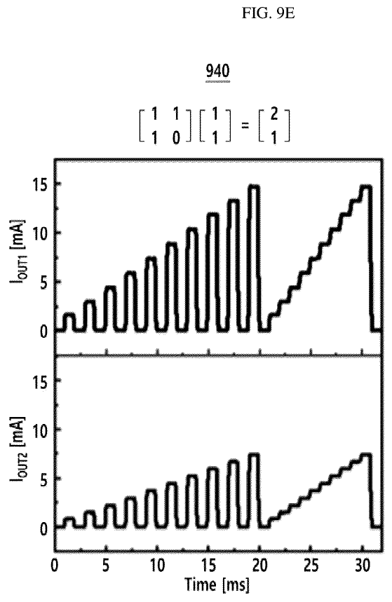

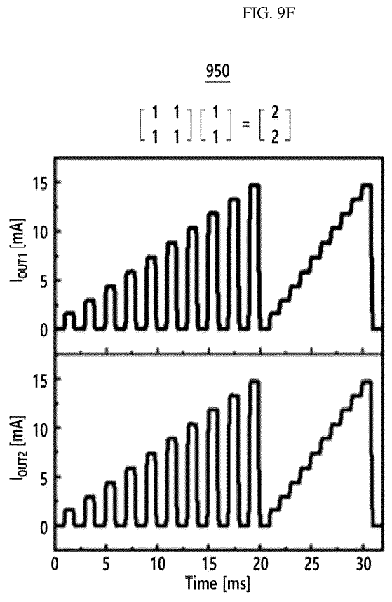

FIGS. 9A to 9F are timing diagrams showing the MAC matrix operation results according to the weight update of the binarized neural network circuitry using silicon-gated diodes according to one embodiment of the present disclosure.

The matrix operation of the timing diagrams shown in FIGS. 9A to 9F refers to the matrix equation on each timing diagram.

During all matrix operations, the weight voltage is fixed at 1 V and the input voltage may have 0 V or a value between 1 V and 2V.

All matrix equations commonly include

$$[ \begin{matrix}{IN}_{1} \\ {IN}_{2}\end{matrix} ] = [ \begin{matrix}1 \\ 1\end{matrix} ] ,$$

which indicates that the V_{IN} pulse in FIG. 7B is applied to V_{IN1} and V_{IN2}.

That is, as the weights of the 2×2 array elements change while both inputs “1” and “2” are fixed to “1”, the operation result meets the matrix equation.

FIG. 9A shows a timing diagram 900 corresponding to a case in which the first output current (I_{OUT1}) is measured as “0” and the second output current (I_{OUT2}) is measured as “0” among MAC matrix operations.

The matrix operation according to the timing diagram 900 may be the same as the matrix operation on the timing diagram 900.

During matrix operation, the weight voltage is 1 V and the input voltage may have 0 V or a value between 1 V and 2 V.

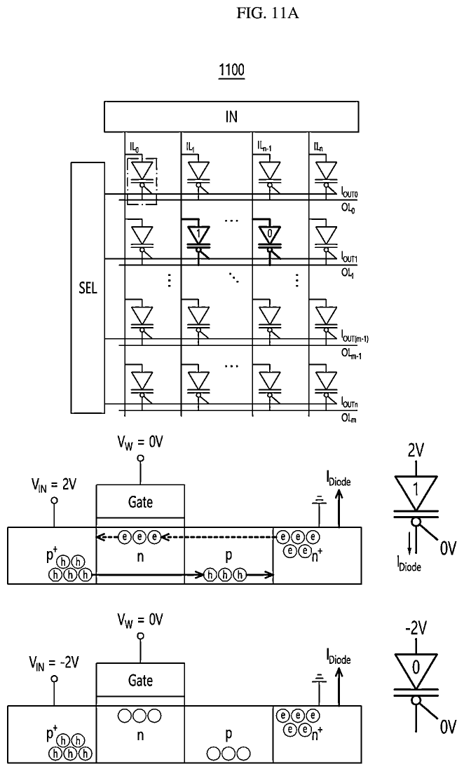

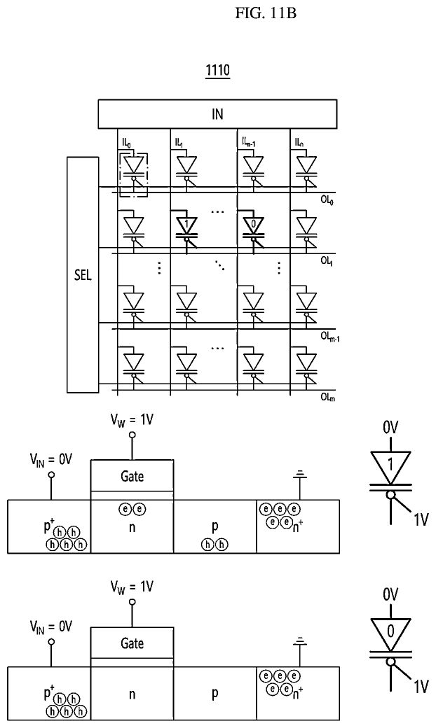

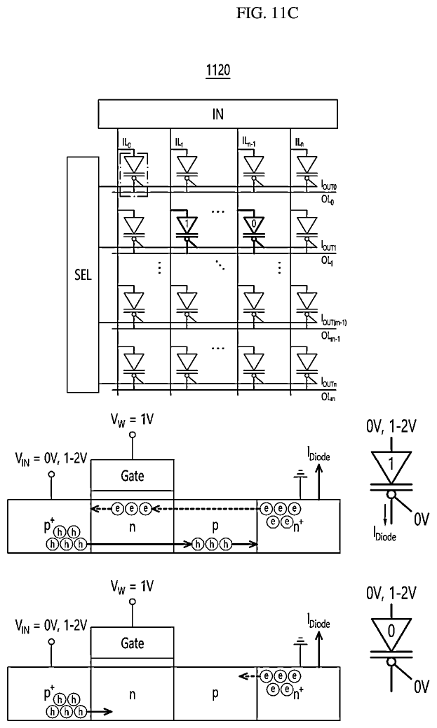

FIG. 11C illustrates a case of performing a matrix operation.

FIG. 9B shows a timing diagram 910 corresponding to a case in which the value according to the first output current (I_{OUT1}) is measured as “1” and the value according to the second output current (I_{OUT2}) is measured as “0” among MAC matrix operations.

The matrix operation according to the timing diagram 910 may be the same as the matrix operation on the timing diagram 910.

FIG. 9C shows a timing diagram 920 corresponding to a case in which the value according to the first output current (I_{OUT1}) is measured as “1” and the value according to the second output current (I_{OUT2}) is measured as “1” among MAC matrix operations.

The matrix operation according to the timing diagram 920 may be the same as the matrix operation on the timing diagram 920.

FIG. 9D shows a timing diagram 930 corresponding to a case in which the value according to the first output current (I_{OUT1}) is measured as “2” and the value according to the second output current (I_{OUT2}) is measured as “0” among MAC matrix operations.

The matrix operation according to the timing diagram 930 may be the same as the matrix operation on the timing diagram 930.

FIG. 9E shows a timing diagram 940 corresponding to a case in which the value according to the first output current (I_{OUT1}) is measured as “2” and the value according to the second output current (I_{OUT2}) is measured as “1” among MAC matrix operations.

The matrix operation according to the timing diagram 940 may be the same as the matrix operation on the timing diagram 940.

FIG. 9F shows a timing diagram 950 corresponding to a case in which the value according to the first output current (I_{OUT1}) is measured as “2” and the value according to the second output current (I_{OUT2}) is measured as “2” among MAC matrix operations.

The matrix operation according to the timing diagram 950 may be the same as the matrix operation on the timing diagram 950.

The above-described matrix operations may be summarized as shown in Equation 1 below.

$$[ \begin{matrix}{W}_{11} & {W}_{12} \\ {W}_{21} & {W}_{22}\end{matrix} ] [ \begin{matrix}{IN}_{1} \\ {IN}_{2}\end{matrix} ] = [ \begin{matrix}{OUT}_{1} \\ {OUT}_{2}\end{matrix} ] \qquad [ Equation 1 ]$$

In Equation 1, W may represent a binarized weight (conductance), IN may represent an input signal (voltage), and OUT may represent an output signal (current) according to a matrix operation.

According to the timing diagrams 900 to 950, when the output current according to the first output current (I_{OUT1}) and the second output current (I_{OUT2}) is 7.5 mA, it is “1”. When the output current is 15 mA, it is “2”. When the output current is less than 7.5 mA, it is “0”.

However, according to the above-mentioned example, 7.5 mA is not limited to meaning output “1”. Regardless of the input voltage, when the output current is 0 mA, it means output “0”. In contrast, when the output current is measured at a certain level according to the input voltage, it may mean “1”.

This proportional relationship may be confirmed through FIG. 6B. Output “1” corresponds to one element. In the timing diagram 950, the output current is twice the current of one element compared to the input voltage, so it may mean output “2”.

The binarized neural network circuitry using silicon-gated diodes may perform a matrix operation for each weight, in this case, the output of the matrix MAC operation has high consistency with a simplified vector-matrix multiplication (VMM) equation due to the high uniformity of the silicon-gated diode.

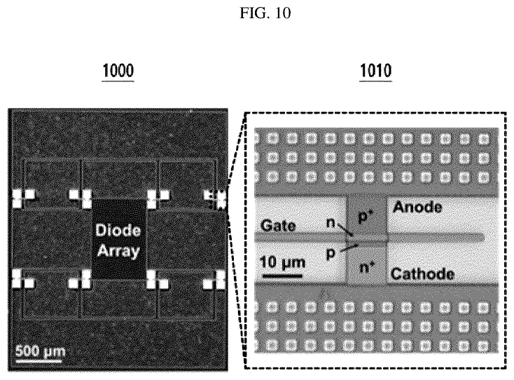

FIG. 10 includes the optical images of a silicon-gated diode according to one embodiment of the present disclosure.

FIG. 10 shows the optical images of the silicon-gated diode according to one embodiment of the present disclosure.

In FIG. 10, an image 1010 shows an enlarged portion of an image 1000.

For example, the image 1000 and the image 1010 may be optical images of a silicon-gated diode for performing a matrix MAC operation between the binarized weight of the BNN and an analog input.

FIGS. 11A to 11C are diagrams explaining the arithmetic operations of a binarized neural network circuitry using silicon-gated diodes according to one embodiment of the present disclosure.

FIG. 11A shows weight update in the arithmetic operation of the binarized neural network circuitry using silicon-gated diodes according to one embodiment of the present disclosure.

Referring to FIG. 11A, in a weight update operation 1100, the binarized weight (W) matrix is V_{IN} (2.0 or −2.0 V) and the silicon-gated diode selected from the array with V_{W}=0.0 V rises (or depresses) at V_{IN} of 2.0 V (−2.0 V).

FIG. 11B shows a standby state in the arithmetic operation of the binarized neural network circuitry using silicon-gated diodes according to one embodiment of the present disclosure.

Referring to FIG. 11B, in a standby operation 1110, 1 V is applied to all weight lines, and 0 V occurs in all input lines.

The silicon-gated diode maintains a memory state with a very low output current (I_{Diode}).

FIG. 11C shows a multiplication operation in the arithmetic operation of the binarized neural network circuitry using silicon-gated diodes according to one embodiment of the present disclosure.

Referring to FIG. 11C, in a multiplication operation 1120, the diode selected from the array may be V_{W}=1.0 V and V_{IN}=0.0 V or V_{IN}=1.1-2.0 V.

I_{OUT}, the product of an input voltage and a binarized weight, may be obtained from the sum of the output current (I_{Diode}).

In the above-described specific embodiments, elements included in the disclosure are expressed in singular or plural in accordance with the specific embodiments shown.

It should be understood, however, that the singular or plural representations are to be chosen as appropriate to the situation presented for the purpose of description and that the above-described embodiments are not limited to the singular or plural constituent elements. The constituent elements expressed in plural may be composed of a single number, and constituent elements expressed in singular form may be composed of a plurality of elements.

In addition, the present disclosure has been described with reference to exemplary embodiments, but it should be understood that various modifications may be made without departing from the scope of the present disclosure.

Therefore, the scope of the present disclosure should not be limited by the embodiments, but should be determined by the following claims and equivalents to the following claims.

1. A binarized neural network circuitry, comprising:
a plurality of silicon-gated diodes in which a diode structure as a channel area is located between an anode terminal and a cathode terminal, a gate terminal is located on the diode structure to implement unidirectional switching through potential barrier control in the channel area based on different voltages applied to each of the anode terminal and the gate terminal, and memory characteristics are realized as holes or electrons accumulate in the potential well due to a positive feedback loop,
wherein the silicon-gated diodes operate as synaptic elements in a memory array connected in parallel, and results of a multiply-accumulate (MAC) operation are output based on an input signal applied from an input line processor connected to the memory array and a weight update signal applied from a synapse line processor connected to the memory array.

2. The binarized neural network circuitry according to claim 1, wherein the silicon-gated diode receives an anode voltage of the anode terminal as the input signal, generates a latch-up phenomenon due to the positive feedback loop as the applied input signal increases in a positive direction, has any one of two memory states for the channel area, receives a gate voltage of the gate terminal as the weight update signal to control the input signal causing the latch-up phenomenon, updates a synaptic state associated with the memory state according to application of the input signal and the weight update signal, and performs the MAC calculating function according to the synaptic weight.

3. The binarized neural network circuitry according to claim 2, wherein the silicon-gated diode outputs a current signal corresponding to any one of “0” to “1” as an operation result by performing a multiplication operation between a continuous input from “0” to “1” as the applied input signal increases in a positive direction and a synaptic weight of any one of a “0” state and a “1” state corresponding to the two memory states.

4. The binarized neural network circuitry according to claim 3, wherein, in the silicon-gated diode, in a case of a potentiation operation in which the synaptic weight is updated to the “1” state, an operation result is output as a current signal in proportion to the applied input signal, and in a case of a depression operation in which the synaptic weight is updated to the “0” state, a current signal is output at 0 mA regardless of the applied input signal.

5. The binarized neural network circuitry according to claim 2, wherein, when the synaptic weight is in a “1” state, the silicon-gated diode outputs a cathode current of the cathode terminal in a form similar to a graph shape of a rectified linear unit (ReLU) function, regardless of the gate voltage.

6. The binarized neural network circuitry according to claim 1, wherein the memory array connects the anode terminal, the gate terminal, and the cathode terminal in parallel in the silicon-gated diodes to form an input line, a weight line, and an output line, respectively,
wherein the input line is arranged perpendicular to the weight line and the output line, and the weight line and the output line are arranged in parallel.

7. The binarized neural network circuitry according to claim 6, wherein the input line receives the input signal, the weight line receives the weight update signal, and the output line outputs the MAC operation result based on the input signal and the weight update signal to a next artificial neural network.

8. The binarized neural network circuitry according to claim 7, wherein, in the memory array, the silicon-gated diodes are connected in a form of N×M, and through a multiplication operation of a synaptic weight that is updated based on an input signal applied to the input line and a weight update signal applied to the weight line, each current is added through the output line and a sum operation is performed to output the MAC operation results as a synaptic weight matrix.

9. The binarized neural network circuitry according to claim 8, wherein, in the memory array, when the N and the M are “2”, the input signal consists of a first input signal and a second input signal, the synaptic weight consists of a first synaptic weight to a fourth synaptic weight, a first current and a second current are output to the output line, and the synaptic weight matrix consisting of the first current and the second current is calculated as a result of a vector matrix multiplication operation of the synaptic weight and the input signal.

10. The binarized neural network circuitry according to claim 9, wherein, in the memory array, when both the first and second input signals are applied while the weight update signal is fixed at 1 V, a value of the first current is twice a value of the second current, and afterwards, when only the first input signal is applied, a value of the first current is equal to a value of the second current.

11. The binarized neural network circuitry according to claim 10, wherein, in the memory array, when only the second input signal is applied, only the first current has a value proportional to the second input signal, and when the first input signal and the second input signal are not applied, the first current and the second current are measured close to 0 mA.

12. The binarized neural network circuitry according to claim 1, wherein the silicon-gated diode comprises any one of a single silicon-gated diode, a double silicon-gated diode, and a triple silicon-gated diode.
